(19) United States
(12) Patent Application Publication
(10) Pub. No.: US 2025/0145520 A1
(43) Pub. Date: May 8, 2025

(54) COATED SUBSTRATE

(71) Applicant: Schott AG, Mainz (DE)

(72) Inventors: Christian Henn, Frei-Laubersheim (DE); Ashish Lepcha, Wiesbaden (DE); Andreas Hahn, Hochstetten-Dhaun (DE); Matthias Bockmeyer, Mainz (DE)

(73) Assignee: Schott AG, Mainz (DE)

(21) Appl. No.: 18/833,589

(22) PCT Filed: Jan. 20, 2023
(86) PCT No.: PCT/EP2023/051339

§ 371 Date: Jul. 26, 2024

(30) Foreign Application Priority Data
Jan. 26, 2022 (EP) 22153429.0

(51) Int. Cl. C03C 17/245; C23C 14/00; C23C 14/02; C23C 14/34; C23C 14/35

(52) U.S. Cl. CPC C03C 17/245; C23C 14/0036; C23C 14/021; C23C 14/3407; C23C 14/35; C03C 2217/23; C03C 2218/155; C03C 2218/156

(57) ABSTRACT

Herein a specific coated substrate and a specific method for the production of a coated substrate is disclosed.

### CROSS-REFERENCE TO RELATED APPLICATIONS

This application is a national stage entry under 35 U.S.C. § 371 of International Patent Application No. PCT/EP2023/051339 entitled “COATED SUBSTRATE,” filed on Jan. 20, 2023, which is incorporated in its entirety herein by reference. International Patent Application No. PCT/EP2023/051339 claims priority to European Patent Application No. 22153429.0 filed on Jan. 26, 2022, which is incorporated in its entirety herein by reference.

### BACKGROUND OF THE INVENTION

### 1. Technical Field of the Invention

The present invention is directed towards coated substrates and to articles including coated substrates.

### 2. Description of the Related Art

Substrates, like glass or glass ceramic plates, are commonly used to cover hobs. The top surface of the glass plate may be coated by one or more coatings. For example, the glass plate may have a scratch resistant coating to reduce scratches on the surface of the glass plate and, in addition, a decor in-between the scratch resistant coating and the substrate to indicate the cooking zones. Several scratch resistant coatings are already known, e.g. WO 2014/135490 A1 and WO 2012/013302 A1. However, the requirements concerning the quality of the scratch resistant coating permanently increases.

### SUMMARY AND OBJECT OF THE APPLICATION

It is an object of the present application to provide a coated substrate having improved quality and a method for the production of said coated substrate. In detail, it is an object of the present invention to provide a coated substrate exhibiting one or more of:
improved scratch resistance;
improved heat resistance;
improved resistance to alkaline solutions;
improved resistance to acidic solutions;
improved gliding properties;
improved adhesion of the coating or the coating and the decor;
reduced delamination; and/or
improved protection of the substrate and/or the decor.

In addition, it is an objection of the present invention to provide an improved method for the production of a coated substrate. In detail, it is an object of the present invention to provide a method for the production of a coated substrate, preferably according to any embodiment described herein, exhibiting one or more of:
reliably producing the coated substrate described herein
increased applying speed;
reduced costs;
increased production reliability; and/or
reduced production fluctuations.

These objects are solved by a coated substrate for a hob, wherein the substrate comprises a coating comprising a layer, wherein the layer consists of a composition A comprising Yttrium and Zirconium, wherein the content of Zirconium in composition A is 75 weight-% or less, preferably 65 weight-% or less, more preferably 55 weight-% or less, wherein the Martens hardness of the coating is 4.5 GPa or more, wherein, after a heat treatment, the color distance ΔE is 4.0 or less.

The Martens hardness of the coating may even be 5.0 GPa or more. Preferably, the Martens hardness of the coating is 5.5 GPa or more, more preferably 6.0 GPa or more, more preferably 6.5 GPa or more, more preferably 7.0 GPa or more, more preferably 7.5 GPa or more, more preferably 8.0 GPa or more, more preferably 8.5 GPa or more, more preferably 9.0 GPa or more; and/or, preferably and the Martens hardness of the coating is 20.0 GPa or less, preferably 18.0 GPa or less, more preferably 16.0 or less, more preferably 14.0 or less, more preferably 12.0 or less, more preferably 11.0 or less, more preferably 10.0 or less. Thus, the scratch resistance can be further improved. Especially, if the Martens hardness of the is coating is 6.0 GPa or more, more preferably 6.5 GPa or more, more preferably 7.0 GPa or more, more preferably 7.5 GPa or more, more preferably 8.0 GPa or more, more preferably 8.5 GPa or more, more preferably 9.0 GPa or more, the scratch resistance is significantly improved.

After a heat treatment, the color distance ΔE may even be 3.5 or less. Preferably, after the heat treatment, the color distance ΔE is 3.0 or less, more preferably 2.5 or less, more preferably 2.0 or less, more preferably 1.5 or less, more preferably 1.0 or less, more preferably 0.5 or less. If the coated substrate fulfills this parameter, the heat resistance is further improved. Especially, if, after a heat treatment, the color distance ΔE is 3.5 or less, preferably 3.0 or less, more preferably 2.5 or less, more preferably 2.0 or less, more preferably 1.5 or less, more preferably 1.0 or less, more preferably 0.5 or less, the heat resistance is significantly improved.

Preferably, the heat treatment is tempering the coated substrate to a temperature T1 for a time t1, wherein the temperature T1 is 300° C., preferably 400° C., more preferably 490° C., more preferably 580° C., more preferably 670° C., more preferably 760° C., more preferably 850° C., more preferably 940° C.; and/or, preferably and, wherein the time t1 is 15 hours, preferably 30 hours, more preferably 45 hours, more preferably 60 hours, more preferably 75 hours, more preferably 90 hours, more preferably 105 hours, more preferably 120 hours, more preferably 135 hours, more preferably 150 hours. The inventors recognized that surprisingly, if the temperature T1 is 300° C., preferably 400° C., more preferably 490° C., and the time t1 is 75 hours, preferably 90 hours, more preferably 120 hours, more preferably 150 hours, and the color distance ΔE is within the above described ranges, the coated substrate is particularly suitable for a gas hob. Further, the inventors recognized that surprisingly, if the temperature T1 is 580° C., preferably 670° C., and the time t1 is 75 hours, preferably 90 hours, more preferably 120 hours, more preferably 150 hours, and the color distance ΔE is within the above described ranges, the coated substrate is further particularly suitable for an induction hob. In addition, the inventors recognized that surprisingly, if the temperature T1 is 670° C., preferably 760° C., and the time t1 is 75 hours, preferably 90 hours, more preferably 120 hours, more preferably 150 hours, and the color distance ΔE is within the above described ranges, the coated substrate is further particularly suitable for a radiant hob. Moreover, inventors recognized that surprisingly, if the temperature T1 is 850° C., preferably 940° C., and the time t1 is 105 hours, preferably 120 hours, more preferably 135 hours, more preferably 150 hours, and the color distance ΔE is within the above described ranges, the coated substrate is further particularly suitable for particularly sophisticated applications.

The degree of crystallinity of the coating is not particularly limited. Preferably, the coating is at least partially crystalline, more preferably at least partially hexagonal, rhombohedral and/or cubic, more preferably at least partially cubic. The inventors recognized that surprisingly if the coating is at least partially crystalline, preferably at least partially hexagonal, rhombohedral and/or cubic, more preferably at least partially cubic, the resistance of the coating is improved and the delamination is reduced. Especially, if the coating exhibits at least partially a cubic pyrochlore structure of the formula X₂^{III}(Z₂^{N}O₇), the resistance of the coating is further improved and the delamination is further reduced.

According to a preferred embodiment, the coating shows a peak between 33° and 36° in the 2-theta-scale of a XRD analysis and/or the coating shows a peak between 28° and 30° in the 2-theta-scale. Thus, the resistance of the coating is improved and the delamination is reduced. Especially, if the coating shows a peak between 33° and 36° and a peak between 28° and 30° in the 2-theta-scale, the resistance of the coating is significantly improved and the delamination is significantly reduced.

The crystallite size and the March-Dollase factor of the coating are not particularly limited. Preferably, the crystallite size of the coating is 1 nm to 30 nm or less, preferably 5 nm to 20 nm, more preferably 10 nm to 15 nm and/or the March-Dollase factor of the coating is 0.2 or more, preferably 0.3 or more, more preferably 0.4 or more, more preferably 0.5 or more; and/or, preferably and, 1.0 or less. Thus, the scratch resistance and the gliding properties are further improved and the delamination is further reduced.

The friction and roughness of the coating is not particularly limited. Preferably, the friction of the coating is 0.3 or less, preferably 0.20 or less, more preferably 0.18 or less. If this parameter is fulfilled, the gliding properties of the coating are further improved and thus, the susceptibility to scratches of the coating is further reduced.

In a preferred embodiment, the coating comprises a region wherein the roughness Sq in an area of 300×300 μm, preferably measured by interferometry with an 50× magnification, is 10 nm to 500 nm, preferably 15 nm to 250 nm, more preferably 20 nm to 200 nm and/or the coating comprises a region wherein the arithmetic average roughness Ra is 10 nm to 90 nm, preferably 20 nm to 80 nm, more preferably 30 nm to 70 nm. More preferably, the entire coating exhibits the above described roughness. If this/these parameter(s) is/are fulfilled, the gliding properties of the coating are further improved and thus, the susceptibility to scratches of the coating is further reduced.

The thickness of the coating is not particularly limited. Preferably, the thickness of the coating is 300 nm or more, preferably 400 nm or more, more preferably 500 nm or more, more preferably 600 nm or more, more preferably 700 nm or more, more preferably 800 nm or more, more preferably 900 nm or more, more preferably 1000 nm or more, more preferably 1100 nm or more, more preferably 1200 nm or more, more preferably 1300 nm or more, more preferably 1400 nm or more and/or, preferably and, the thickness of the coating is 5000 nm or less, preferably 4500 nm or less, more preferably 4000 nm or less, more preferably 3500 nm or less, more preferably 3000 nm or less, more preferably 2500 nm or less, more preferably 2000 nm or less, more preferably 1900 nm or less, more preferably 1800 nm or less, more preferably 1700 nm or less, more preferably 1600 nm or less, more preferably 1500 nm or less. The thicker the coating, the better the protection of the substrate was observed. The thinner the coating, the less delamination was observed. Thus, if the thickness of the coating is 300 nm or more, preferably 800 nm or more, more preferably 1000 nm or more; and/or, preferably and, 3000 nm or less, preferably 2000 nm or less, more preferably 1800 or less, the protection is significantly improved and the delamination is significantly reduced.

In a preferred embodiment, after an acidic treatment, the color distance ΔE is 3 or less, more preferably 2.5 or less, more preferably 2.0 or less, more preferably 1.5 or less, more preferably 1.0 or less, more preferably 0.5 or less. More preferably, the acidic treatment is contacting the coating of the coated substrate with an aqueous solution, preferably CH₃COOH.aq or HCl.aq or H₃PO₄.aq or C₆H₈O₇.aq (citric acid), more preferably H₃PO₄.aq, having a pH value P2 and a temperature T2 for a time t2; wherein the pH value P2 is 6, preferably 5, more preferably 4, more preferably 3, more preferably 2, more preferably 1, more preferably 0; wherein the temperature T2 is 20° C., preferably 30° C., more preferably 50° C., more preferably 80° C., more preferably 90° C., more preferably 100° C., more preferably set to the boiling point of the aqueous solution; and wherein the time t2 is 1 hours, preferably 6 hours, more preferably 12 hours, more preferably 24 hours, more preferably 48 hours, more preferably 72 hours. If the coated substrate fulfills this parameter, the resistance to acidic solutions is improved. Especially, if, after an acidic treatment, the color distance ΔE is 1.5 or less, preferably 1.0 or less, more preferably 0.5 or less, the resistance to acidic solutions is significantly improved. The inventors recognized that surprisingly, if the pH value P2 is 3, preferably 2 (H₃PO₄.aq or C₆H₈O₇.aq, preferably H₃PO₄.aq); the temperature T2 is 20° C., preferably 30° C.; the time t2 is 24 hours, preferably 48 hours, more preferably 72 hours; and the color distance ΔE is 1.5 or less, preferably 1.0 or less, more preferably 0.5 or less, the coated substrate is particularly suitable for hobs with customary use. Further, the inventors recognized that surprisingly, if the pH value P2 is 3, preferably 2 (H₃PO₄.aq or C₆H₈O₇.aq, preferably H₃PO₄.aq); the temperature T2 is set to the boiling point of the aqueous solution; the time t2 is 1 h, preferably 6 hours, more preferably 24 hours; and the color distance ΔE is 1.5 or less, preferably 1.0 or less, more preferably 0.5 or less, the coated substrate is further particularly suitable for ambitious applications like professional hobs.

In a preferred embodiment, after an alkaline treatment, the color distance ΔE is 3 or less, more preferably 2.5 or less, more preferably 2.0 or less, more preferably 1.5 or less, more preferably 1.0 or less, more preferably 0.5 or less. More preferably, the alkaline treatment is contacting the coating of the coated substrate with an aqueous solution, preferably NaOH.aq or KOH.aq or Na₂CO₃.aq, more preferably Na₂CO₃.aq, having a pH value P3 and a temperature T3 for a time t3; wherein the pH value P3 is 8, preferably 9, more preferably 10, more preferably 11, more preferably 12, more preferably 13, more preferably 14; wherein the temperature T3 is 20° C., preferably 30° C., more preferably 50° C., more preferably 80° C., more preferably 90° C., more preferably 100° C., more preferably set to the boiling point of the aqueous solution; and wherein the time t3 is 1 hours, preferably 6 hours, more preferably 12 hours, more preferably 24 hours, more preferably 48 hours, more preferably 72 hours. If the coated substrate fulfills this parameter, the resistance to alkaline solutions is improved. Especially, if, after an alkaline treatment, the color distance ΔE is 1.5 or less, preferably 1.0 or less, more preferably 0.5 or less, the resistance to alkaline solutions is significantly improved. The inventors recognized that surprisingly, if the pH value P3 is 12, preferably 13; the temperature T3 is 20° C., preferably 30° C.; the time t3 is 24 hours, preferably 48 hours, more preferably 72 hours; and the color distance ΔE is 1.5 or less, preferably 1.0 or less, more preferably 0.5 or less, the coated substrate is particularly suitable for hobs with customary use. Further, the inventors recognized that surprisingly, if the pH value P3 is 12, preferably 13; the temperature T3 is set to the boiling point of the aqueous solution; the time t3 is 1 h, preferably 6 hours, more preferably 24 hours; and the color distance ΔE is 1.5 or less, preferably 1.0 or less, more preferably 0.5 or less, the coated substrate is further particularly suitable for ambitious applications like professional hobs.

The compressive stress of the coating is not particularly limited. In a preferred embodiment, the coating exhibits a compressive stress of 100 to 3000 MPa, preferably 100 to 2000 MPa, more preferably 100 to 1200 MPa, more preferably 200 to 1000 MPa. Thus, the resistance, especially the scratch resistance is improved.

The color value in transmission and the opacity of the coating is not particularly limited. In a preferred embodiment the coating exhibits a color value in transmission of C* of 20 or less, preferably 15 or less, more preferably 10 or less, more preferably 8 or less, more preferably 7 or less, more preferably 6 or less, more preferably 5 or less and/or the coating exhibits an opacity of 0.0 to 0.3, more preferably 0.01 to 0.25 preferably 0.05 to 0.15. Thus, if the substrate is used in a hob, the color change of a display being beneath the coated substrate in the hob can be reduced and the sharpness of the display can be increased. Consequently, the application area of the coated substrate is increased.

The coating may comprise one or more coating layers, wherein the number of layers is not particularly limited. Preferably, the coating comprises one or more, preferably 2, 3, 4, 5, 6, 7, 8, 9 or 10, layers; preferably wherein all layers are the same. If the coating comprises 2 or more of the same layers, the coating can be produced faster. The inventors recognized that the properties are not significantly different between one thick layer and a coating having the same total thickness and comprising several thin layers.

In a preferred embodiment, the coating consists of the layer and/or the coating is a monolayer. Thus, the homogeneity of the coating can be further improved and the coating can be applied in one step.

The position of the herein described layer within the coating is not particularly limited. Preferably, the layer is the outermost layer of the coating. Thus, the layer protects all subjacent layers and the substrate and consequently, the resistance, especially the scratch resistance, is further improved.

The herein described coating may be in direct contact with the substrate or the coated substrate comprises a decor, preferably a color decor, more preferably wherein the decor is in-between the coating and the substrate. Preferably the coating is at least partially in direct contact with the substrate. The decor might be applied by an inkjet printer process or by a screen printing process, for example, as described in EP 1 743 003 A1, WO 2016/008848 A1, EP 3 067 334 A1, and EP 0 978 493 A1, which are herein incorporated by reference. The inventors recognized that surprisingly if the decor is in-between the coating and the substrate, the adhesion of the decor is further improved and thus, the delamination also in the area, where a decor is present, is reduced and thus, the adhesion is improved.

Another aspect of the present invention is a use of the coated substrate described herein in a hob, an oven, a table, a shower wall, a radiator, a car, a consumer electronic device, a mobile phone, a tablet, a watch, a smart watch, an optical filter, an interference filter, an anti-reflection filter, a mirror, more preferably in an induction hob, a radiant hob or a gas hob.

Further, an aspect of the present invention is a hob, an oven, a table, a shower wall, a radiator, a car, a consumer electronic device, a mobile phone, a tablet, a watch, a smart watch, an optical filter, an interference filter, an anti-reflection filter, a mirror; more preferably an induction hob, a radiant hob or a gas hob; comprising the coated substrate described herein.

Another aspect of the invention is a method for the production of a coated substrate, preferably as described herein, comprising the steps, preferably in this order:
providing a substrate;
applying a layer consisting of a composition A comprising Yttrium and Zirconium by a physical vapor deposition process on the substrate to obtain the coated substrate described herein, wherein the content of Zirconium in composition A is 75 weight-% or less, preferably 65 weight-% or less, more preferably 55 weight-% or less.

If the herein described method is used, the above described coating can be obtained.

In a preferred embodiment, the physical vapor deposition process is a sputter deposition or evaporation process, preferably a sputter deposition process, more preferably a magnetron sputtering process, more preferably an inline magnetron sputtering process, more preferably a high-target-utilization sputtering (HiTUS) process or a high-power impulse magnetron sputtering (HiPIMS) process. Especially, if a magnetron sputtering process is used to produce the coated substrate as described herein, the coating can be reliably applied.

The way of applying the coating is not particularly limited. Preferably, applying a layer consisting of a composition A comprising Yttrium and Zirconium, wherein the content of Zirconium in composition A is 75 weight-% or less, preferably 65 weight-% or less, more preferably 55 weight-% or less, by a physical vapor deposition process on the substrate comprises:
sputtering and depositing a target on the substrate, preferably in the presence of a process gas. Thus, the coating can be reliably applied.

Herein “depositing a target on the substrate” refers to a transfer of target material from the target onto a surface of the substrate in course of the sputtering process.

In a preferred embodiment, the target comprises, preferably consists of, a composition B comprising Yttrium, Zirconium and unavoidable impurities, wherein the content of Zirconium in composition B is 75 weight % or less, preferably 65 weight-% or less, more preferably 55 weight-% or less. The composition B of the target and the composition A of the coating may be the same or different. Preferably, they are different, e.g. the content (weight-%) of oxygen in the coating may be higher than the content (weight-%) of oxygen in the target. Preferably, the ratio of the elements comprised in the target and the ratio of the elements comprised in the coating are similar, i.e. +10%, preferably +5%, more preferably are the same. Thus, the coating can be reliably produced.

In a preferred embodiment, the target is a planar target or a rotatable target, preferably a rotatable target. Thus, the coating can be reliably produced.

The magnetic flux density used in the magnetron sputtering process is not particularly limited. In a preferred embodiment, the magnetic flux density, preferably on at least a part of the surface of the target, is set to 5 mT to 200 mT, preferably 10 mT to 150 mT, more preferably 15 mT to 100 mT, most preferably 20 mT to 80 mT. If the magnetic flux density is in this range, the uniformity of the coating can be improved, the control of the thickness of the coating can be improved and the heat variation of the substrate can be decreased, which in turn leads to an improvement of the resistance of the coating and a reduced delamination.

The applied electric current in the magnetron sputtering process is not particularly limited. In a preferred embodiment, the applied electric current in the physical vapor deposition process is set to 1 A to 1000 A, preferably 20 A to 500 A, more preferably 100 A to 200 A. Thus, the sputtering rate can be improved and the chemical, mechanical and thermal properties can be improved. Consequently, the resistance of the coating and the adhesion of the coating can be improved.

The applied voltage in the magnetron sputtering process is not particularly limited. In a preferred embodiment, the applied voltage in the physical vapor deposition process is set to 50 V to 2000 V, preferably 100 V to 1000 V, most preferably 200 V to 700 V. Thus, the sputtering rate can be improved and the optical, chemical, mechanical and thermal properties can be improved. Consequently, the resistance of the coating and the adhesion of the coating can be improved.

The pressure during the physical vapor deposition process is not particularly limited. In a preferred embodiment, the pressure during the physical vapor deposition process is set to 0.5×10⁻³ bar to 1×10², preferably 1×10⁻³ bar to 1×10⁻² bar, most preferably 2×10⁻³ bar to 8×10⁻³ bar, the pressure during the physical vapor deposition process could also be set to 2×10⁻³ bar, 3×10⁻³ bar, 4×10⁻³ bar, 5×10⁻³ bar, 6×10⁻³ bar, 7×10³ bar, or 8×10⁻³ bar, Thus, optical, chemical, mechanical and thermal properties can be improved and the stability of the plasma can be improved, which in turn improves the resistance of the coating.

The distance between the target and the substrate and the position where the process gas is provided, during the physical vapor deposition process, is not particularly limited. In a preferred embodiment, the distance between the target and the substrate during the physical vapor deposition process is 2 to 40 cm, preferably 4 to 40, more preferably 5 to 20 cm, most preferably 10 to 15 cm and/or a/the process gas is provided between the target and the substrate during the physical vapor deposition process. Thus, the stability of the plasma and the control of the thickness uniformity of the coating can be improved, which in turn improves the resistance of the coating.

The gas flow of oxygen is not particularly limited. Preferably, the process gas comprises oxygen, preferably wherein the gas flow of oxygen is set to 1 sccm to 10000 sccm, preferably 100 sccm to 5000 sccm, more preferably 300 sccm to 3000 sccm. If the gas flow is 1 sccm or more, preferably 100 sccm or more, more preferably 300 sccm or more, the opacity of the coating can be reduced. If the gas flow of oxygen is set to 10000 sccm or less, preferably 5000 sccm or less, more preferably 3000 sccm or less, the stability of the coating process can be improved and the sputtering rate can be enhanced.

The gas flow of argon is not particularly limited. Preferably, the process gas comprises argon, preferably wherein the gas flow of argon is set to 1 sccm to 10000 sccm, preferably 100 sccm to 5000 sccm, more preferably 300 sccm to 4000 sccm. If the gas flow of argon is set to 1 sccm or more, preferably 100 sccm or more, more preferably 300 sccm or more, the stability of the plasma can be improved. If the gas flow of argon is set to 10000 sccm or less, preferably 5000 sccm or less, more preferably 4000 sccm or less, plasmapolymerization can be avoided and optical, chemical, mechanical and thermal properties can be improved.

In a preferred embodiment, the method further comprises the step: annealing the substrate to 100° C. to 500° C. preferably 200° C. to 400° C., preferably before and/or during the magnetron sputtering process. Thus, the adhesion of the coating on the substrate can be improved and the ablation of the coating can be decreased. If not stated otherwise, the substrate temperature is measured on the substrate surface.

The deposit rate of the layer is not particularly limited. Preferably, the layer is applied with a deposit rate of 10 nm*m/min to 1000 nm*m/min, preferably 30 nm*m/min to 500 nm*m/min, more preferably 40 nm*m/min to 100 nm*m/min, more preferably 45 nm*m/min to 80 nm*m/min, more preferably 50 nm*m/min to 75 nm*m/min. Thus, the resistance of the coating can be improved.

In a preferred embodiment, the application step is repeated, preferably 2 times, preferably 3 times, more preferably 4 times, more preferably 5 times, more preferably 6 times, more preferably 7 times, more preferably 8 times, more preferably 9 times, more preferably 10 times, to obtain a coated substrate wherein the coating comprises one or more, preferably 2, 3, 4, 5, 6, 7, 8, 9 or 10, layers; preferably wherein all layers are the same. Thus, a coating having improved quality and reduced cycle time can be obtained.

As described above, the composition(s) A and/or B comprise(s) Yttrium and Zirconium. In accordance with a further embodiment, the composition(s) A and/or B further comprise(s) one or more of Silicon, Aluminum, Titanium, and/or Hafnium. The composition(s) A and/or B may further comprise unavoidable impurities. Herein, preferably the unavoidable impurities are selected from Fe, Ti, Zn, Cu, Mn, Co, Ca, Nb, Gd, Eu, Er, Mo, La, Lu, Mg, Pr, Sm, W, Ni, Yb, Nd, O, N; and/or the unavoidable impurities have a content of 5 weight-% or less, preferably 4 weight-% or less, more preferably 3 weight-% or less, more preferably 2 weight-% or less, more preferably 1 weight-% or less, more preferably 0.8 weight-% or less, more preferably 0.6 weight-% or less, more preferably 0.4 weight-% or less, more preferably 0.2 weight-% or less, more preferably 0.1 weight-% or less, more preferably 0.05 weight-% or less, more preferably 0.01 weight-% or less, more preferably 0.005 weight-% or less, more preferably 0.001 weight-% or less. Thus, the resistance of the coating can be further improved.

In a preferred embodiment, the content of Yttrium in the composition(s) A and/or B is 25 weight-% or more. It has been found that a corresponding coating comprising 25 or more weight-% Yttrium and 75 or less weight-% Zirconium may exhibit a specifically high Martens Hardness of 6 GPa or more.

In a preferred embodiment, the composition(s) A and/or B comprise(s) Yttrium and Zirconium, wherein the following equations are fulfilled:
((Zr/(Zr+Y))*100≥40, preferably ((Zr/(Zr+Y))*100≥45; and
(Y/(Zr+Y)*100≥40, preferably (Y/(Zr+Y)*100≥45;
wherein Zr is the content (weight-%) of Zirconium in composition(s) A and/or B,
wherein Y is the content (weight-%) of Yttrium in composition(s) A and/or B,
wherein the Martens hardness of the coating is 6 GPa or more, preferably 7 GPa or more, and wherein after a heat treatment, the color distance ΔE is 4 or less, preferably ΔE is 3 or less, most preferably ΔE is 2 or less. A corresponding coating can for example be obtained by reactive magnetron sputtering in a mostly oxygen and argon containing atmosphere or from a ceramic target in a mostly argon containing atmosphere, wherein the pressure of the sputtering process can for example be set to 1-8×10⁻³ mbar,

In the above embodiment, it is further preferred that the composition(s) A and/or B further comprise(s)

Silicon, wherein the following equations are fulfilled:
((Zr/(Zr+Y+Si))*100≥40, preferably ((Zr/(Zr+Y+Si))*100≥45, more preferably ((Zr/(Zr+Y+Si))*100≥50;
(Y/(Zr+Y+Si)*100≥40, preferably (Y/(Zr+Y+Si)*100≥45, and 0,1≤((Si/(Zr+Y+Si))*100≤4, preferably 0,1≤((Si/(Zr+Y+Si))*100≤2,
wherein Zr is the content (weight-%) of Zirconium in composition(s) A and/or B,
wherein Y is the content (weight-%) of Yttrium in composition(s) A and/or B,
wherein Si is the content (weight-%) of Silicon in composition(s) A and/or B,
wherein the Martens hardness of the coating is 6 GPa, preferably 7 GPa or more and wherein after a heat treatment, the color distance ΔE is 4 or less, preferably ΔE is 3 or less, most preferably ΔE is 2 or less. A corresponding coating can for example be obtained by reactive magnetron sputtering in a mostly oxygen and argon containing atmosphere or from a ceramic target in a mostly argon containing atmosphere, wherein the pressure of the sputtering process can for example be set to 1-8×10⁻³ mbar,

In the above embodiment, it is further preferred that the composition(s) A and/or B further comprise(s) Aluminum, wherein the following equation is fulfilled:
0,5≤((Al/(Zr+Y+Si+Al))*1000≤50, preferably 1≤((Al/(Zr+Y+Si+Al))*1000≤10; wherein Al is the content (weight-%) of Aluminum in composition(s) A and/or B.

In the above embodiment, it is further preferred that the composition(s) A and/or B further comprise(s) Hafnium, wherein the following equation is fulfilled:
0,1≤((Hf/(Zr+Y+Si+Al+Hf))*100≤5, preferably 1≤((Hf/(Zr+Y+Si+Al+Hf))*100≤2,
wherein Hf is the content (weight-%) of Hafnium in composition(s) A and/or B.

In the above embodiment, it is further preferred that the composition(s) A and/or B further comprise(s) Hafnium, wherein the following equations are fulfilled:

$$( ( Zr / ( Zr + Y + Si + Hf ) ) * 100 \geq 50 ;$$

$$( ( Y / ( Zr + Y + Si + Hf ) ) * 100 \geq 45 ;$$

$$1 \leq ( ( Si / ( Zr + Y + Si + Hf ) ) * 100 \leq 2 ;$$

$$0.5 \leq ( ( Al / ( Zr + Y + Si + Al + Hf ) ) * 1000 \leq 10 ; and$$

$$0.1 \leq ( ( Hf / ( Zr + Y + Si + Al + Hf ) ) * 100 \leq 5$$

wherein Zr is the content (weight-%) of Zirconium in composition(s) A and/or B,
wherein Y is the content (weight-%) of Yttrium in composition(s) A and/or B,
wherein Si is the content (weight-%) of Silicon in composition(s) A and/or B,
wherein Al is the content (weight-%) of Aluminum in composition(s) A and/or B, and
wherein Hf is the content (weight-%) of Hafnium in composition(s) A and/or B.

In a further preferred embodiment, the composition(s) A and/or B comprise(s) Zirconium, Yttrium and Silicon, wherein the following equations are fulfilled:

$$( ( Zr / ( Zr + Y + Si ) ) * 100 \geq 30 ; and$$

$$( ( Y / ( Zr + Y + Si ) ) * 100 \leq 10 ;$$

wherein Zr is the content (weight-%) of Zirconium in composition(s) A and/or B,
wherein Y is the content (weight-%) of Yttrium in composition(s) A and/or B,
wherein Si is the content (weight-%) of Silicon in composition(s) A and/or B,
wherein the Martens hardness of the coating is 4.5 GPa or more and wherein after a heat treatment, the color distance ΔE is 4 or less, preferably 3 or less, preferably 2 or less, preferably 1 or less. A corresponding coating can for example be obtained by reactive magnetron sputtering in a mostly oxygen and argon containing atmosphere or from a ceramic target in a mostly argon containing atmosphere, wherein the pressure of the sputtering process can for example be set to 1-8×10⁻³ mbar,

In the above embodiment, it is further preferred that the following equation is fulfilled:

$$30 \leq ( ( Si / ( Zr + Y + Si ) ) * 100 \leq 60 ;$$

wherein after a heat treatment, the color distance ΔE is 2 or less, preferably 1 or less, most preferably 0.5 or less.

In a further preferred embodiment, the composition(s) A and/or B further comprise(s) Carbon.

In the above embodiment, it is further preferred that the composition(s) A and/or B comprise(s) Yttrium, Zirconium, Aluminum, Silicon, Hafnium and Carbon, wherein the following equations are fulfilled:

$$( ( Zr / ( Zr + Y + Si + Hf + C ) ) * 100 \geq 50 ;$$

$$( ( Y / ( Zr + Y + Si + Hf + C ) ) * 100 \geq 45 ;$$

$$1 \leq ( ( Si / ( Zr + Y + Si + Hf + C ) ) * 100 \leq 2 ;$$

$$0.5 \leq ( ( Al / ( Zr + Y + Si + Al + Hf + C ) ) * 1000 \leq 10 ;$$

$$1 \leq ( ( Hf / ( Zr + Y + Si + Hf + C ) ) * 100 \leq 2 ; and$$

$$0.5 \leq ( ( C / ( Zr + Y + Si + Al + Hf + C ) ) * 1000 \leq 10 ;$$

wherein Zr is the content (weight-%) of Zirconium in composition(s) A and/or B,
wherein Y is the content (weight-%) of Yttrium in composition(s) A and/or B,
wherein Si is the content (weight-%) of Silicon in composition(s) A and/or B,
wherein Al is the content (weight-%) of Aluminum in composition(s) A and/or B,
wherein Hf is the content (weight-%) of Hafnium in composition(s) A and/or B, and
wherein C is the content (weight-%) of Carbon in composition(s) A and/or B.

The size and shape of the substrate is not particularly limited. It may be flat or bent or have a complex shape. Preferably, the substrate is a plate, preferably having:
a length of 10 cm to 700 cm, preferably 20 cm to 200 cm, more preferably 50 cm to 150 cm; and/or, preferably and, a width of 10 cm to 400 cm, preferably 20 cm to 200 cm, more preferably 50 cm to 150 cm; and/or, preferably and, a height of 0.1 mm to 5 cm, preferably 1 mm to 10 mm, more preferably 2 to 6 mm. Especially, if the substrate is a plate, the gliding properties and the adhesion of the coating are improved. If the plate has a length and width of 20 cm to 200 cm, preferably 50 cm to 150 cm, and a height of 1 mm to 10 mm, preferably 2 to 6 mm, the layer can be homogeneously and reliably applied and thus, the production fluctuations are reduced.

The area of the coating is not particularly limited. In case the substrate is a plate, the coating might be either on one side of the plate or on both sides of the plate. Preferably, the substrate is a plate comprising a surface, wherein at least 50% [cm2/cm2], preferably at least 75% [cm2/cm2], more preferably at least 80% [cm2/cm2], more preferably at least 90% [cm2/cm2], more preferably at least 95% [cm2/cm2], of the surface (i.e. of one side of the plate) is coated, more preferably wherein the entire surface, i.e. one side of the substrate, is coated. Thus, the protection of the substrate and/or the decor are improved. In a further preferred embodiment, the plate is only coated on one side and this side is the side facing upwards when installed in a hob.

The material of the substrate is not particularly limited. Preferably, the substrate is a glass ceramic or glass, preferably comprising, more preferably consisting of, in mass-%:
SiO² 60 to 90%, preferably 76% to 90%;
B₂O₃ 0 to 20%;
Al₂O₃ 0 to 20%;
Li₂O 0 to 10%;
Na₂O 0 to 10%;
K₂O 0 to 10%;
MgO 0 to 10%;
CaO 0 to 10%;
SrO 0 to 10%; and
BaO 0 to 10%;
preferably and unavoidable impurities.

Thus, the adhesion of the coating or the coating and the decor is improved, the delamination is reduced and the protection of the substrate and/or the decor is improved.

Preferably, the substrate is a glass or glass ceramic. More preferably, the substrate is a borosilicate glass, an alumosilicate glass, a lithiumalumosilicate glass, a sodalime glass, a sapphire glass, and/or a glass ceramic, preferably a lithiumalumosilicate glass ceramic, more preferably wherein the substrate is chemically strengthened and/or thermally strengthened, or not strengthened, more preferably a not strengthened glass ceramic, more preferably a not strengthened lithiumalumosilicate glass ceramic. Thus, the adhesion of the coating or the coating and the decor is improved, the delamination is reduced and the protection of the substrate and/or the decor is improved.

In a preferred embodiment, the coated substrate is producible, preferably is produced, by the method described herein. Thus, the coated substrate can be reliably provided and the herein described improvements are reliably achieved.

### BRIEF DESCRIPTION OF THE DRAWINGS

FIG. 1 is a schematic depiction of a side view of a coated substrate according to an embodiment; and

FIG. 2 is an X-ray diffraction spectrum of the coating.

In the following description of embodiments, the same reference numeral designate similar components.

### DETAILED DESCRIPTION OF THE INVENTION

### Definitions

Preferably, if not stated otherwise, the herein described parameters are determined according to the following:

Color distance: The color distance can be measured using a portable sphere type spectrophotometers with vertical alignment, e.g. a Konica Minolta CM-700d or CM-600d; measuring range 400 to 700 nm; illumination CIE-D65, gloss value: 8°; calibrated against a black surface. The color distance is the change of the measured Lab value measured before and after the respective treatment, wherein the untreated coated substrate and treated coated substrate, respectively, lie on the same black surface during the measurement of the Lab value. Martens hardness: Martens hardness can be measured by a nanoindenter equipment with Berkovich Indenter at a force of 5 mN, for example the nanoindenter CSM NHT.

Content: The content of the elements in the coating, e.g. yttrium, zirconium, silicon, aluminum, oxygen and nitrogen, can be measured using EDX spectroscopy, for example using the EDX spectroscope from Oxford instruments, model Inca×-act.

Crystal system and Peak in the 2-theta-scale: The crystal system of the layer or coating and/or the the peak in the 2-theta-scale can measured by thin film XRD, e.g. the thin film XRD from Philips company, model X′pert pro.

Crystallite size and March-Dollase factor: The crystallite sizes (KGR) and the relative phase proportions (in weight-%) were determined using a Rietveld analysis. The relative phase proportions indicate the proportion of crystals in the layer compared to the substrate (HQMK). This means that the thicker and/or more crystalline the layer, the lower the measured proportion of the substrate (HQMK). The crystalline phases of the layers showed a strong preferential direction. The preferred direction was corrected using the so-called March-Dollase factor (MD factor). The lower the factor, the stronger is the texture in direction (122) at the Zr₃Y₄O₁₂-phase and in direction (010) and (011), respectively, at the Y_{0.12}Zr_{0.85}O_{1.93}-phase (MD=1.0 no preferred direction).

Friction: The friction can be measured by a CSM Micro combi tester (CSM company).

Roughness: The roughness Rq and the arithmetic average roughness Ra can be measured using a white light interferometry system, for example Keyence Model VK.

Thickness of the coating: The thickness is measured using a reflection measurement system by spectrometer of the company NXT, model TCM. Preferably, the thickness of the coating is measured at a position, where the coating is in direct contact with the substrate and not decor is in-between the coating and the substrate.

Compressive stress: The compressive stress is measured by measuring the warp of an uncoated substrate, coating and after coating measuring again to get the warp difference, resulted by the coating. Calculation of the stress is performed by the stoney equation. For the measurement Cyberscan CT 300 can be used.

Color value: The color value in transmission can be measured by a Lambda 950 under 2° with D65 to calculate the C* value.

Opacity: The opacity of the coating can be measured by a densitometer, for example the densitometer X-rite 361T, on a transparent substrate, for example Borofloat 33.

Magnetic flux density: The magnetic flux density can be determined by a magnetometer, e.g. PCE-MFM 3000.

Application method of the coating: The coating is preferably applied by physical vapor deposition, preferably by magnetron sputtering on an inline machine, e.g. Leybold ZV 1200.

There are several ways how to design and further develop the teaching of the present invention in an advantageous way. To this end, it is to be referred to the patent claims subordinate to the independent patent claims, to the above explanation(s) of preferred embodiments, the inventive example(s) and the following example(s) of embodiments illustrated by the figure(s). Herein, all preferred embodiments of the coated substrate also apply for the method and the use described herein and vice versa. The combination of two or more, for example 2, 3, 4 or 5 preferred embodiment is more preferred.

### Examples

In connection with the above-described preferred embodiments and items, by the aid of the figures and examples, generally preferred embodiments and further developments of the teaching will be explained:

### Example 1 (Reference Example)

A glass ceramic substrate (SCHOTT CERAN®) having a size of 50 cm×50 cm×4 mm was cleaned in an ultra-sonic bath. The cleaned substrate was then inserted in the chamber of the magnetron sputtering system ZV1200 from company Leybold. The chamber was evacuated to a final pressure of 5*10⁻⁵ mbar and then the pressure was set to 5*10⁻³ mbar with argon. Then, the coating was applied using the following setting:

Target: planar target; Zr: Y=92:8; purity 99,9 (3N) magnetic flux: 50 mT;
electric current: 20 A;
voltage: 300 V;
pressure: 5×10⁻³ bar;
distance target to substrate: 15 cm;
gas flow of oxygen: 55 sccm;
gas flow of argon: 170 sccm;
substrate temperature: 250° C.;
deposit rate 29.7 nm*m/min;
number of layers: 8.

Thus, a coating was obtained having a thickness of 1500 nm and being at least partially cubic. In addition, the coating exhibits a scratch resistance (Martens hardness was 8 GPa and compressive stress=1000 MPa); heat resistance (580° C. and 75h→ΔE=3.5); resistance to alkaline solutions (Na₂CO₃.aq, pH=10, T=20° C.; t 12 h→ΔE=0.7) and resistance to acid solutions (C₆H₈O₇.aq (citric acid), pH=3, T=20° C.; t 12 h→ΔE=1.2).

### Example 2 (Reference Example)

Example 2 was produced in a similar way to example 1, however, as target a planar target, Mg: Al=30:70 was used. The coating exhibits a ΔE of 9.1 (75 h and 580° C.).

### Example 3 (Inventive Example)

A glass ceramic substrate (SCHOTT CERAN®) having a size of 50 cm×50 cm×4 mm was cleaned, e.g. by a ultrasonic cleaner, by a brush washing machine, by flame pretreatment, by a temperature load or comparable known cleaning option. The sputtering process was carried out in a conventional magnetron sputtering system. The coating was applied using the following setting:
Target composition: Zr: Y=50:50 wt %;
Reactive sputtering in a mostly oxygen and argon containing atmosphere or from a ceramic target in a mostly argon containing atmosphere;
pressure: 1-8×10⁻³ mbar;
Coating thickness: 1000-1800 nm

The coating exhibits a good scratch resistance by a hardness of at least 7 GPa; a good heat resistance of ΔE=2 at 580° C.; a resistance to alkaline solutions (Na₂CO₃.aq, pH=10, T=20° C.; t 12 h→ΔE=1) and resistance to acid solutions (C₆H₈O₇.aq (citric acid), pH=3, T=20° C.; t 12 h→ΔE=1,5). Example 4 (inventive example)

A glass ceramic substrate (SCHOTT CERAN®) having a size of 50 cm×50 cm×4 mm was cleaned, e.g. by a ultrasonic cleaner, by a brush washing machine, by flame pretreatment, by a temperature load or comparable known cleaning option. The sputtering process was carried out in a conventional magnetron sputtering system. The coating was applied using the following setting:

Target composition: Zr: Y: Si=51:47:2 wt %; Reactive sputtering in a mostly oxygen and argon containing atmosphere or from a ceramic target in a mostly argon containing atmosphere;
pressure: 1-8×10⁻³ mbar; Coating thickness: 1000-1800 nm

The coating exhibits a good scratch resistance by a hardness of at least 7 GPa; a good heat resistance of ΔE=1.5 at 580° C.; a resistance to alkaline solutions (Na₂CO₃.aq, pH=10, T=20° C.; t 12 h≥ΔE=1.1) and resistance to acid solutions (C₆H₈O₇.aq (citric acid), pH=3, T=20° C.; t 12 h→ΔE=1).

### Example 5 (Inventive Example)

A glass ceramic substrate (SCHOTT CERAN®) having a size of 50 cm×50 cm×4 mm was cleaned, e.g. by a ultrasonic cleaner, by a brush washing machine, by flame pretreatment, by a temperature load or comparable known cleaning option. The sputtering process was carried out in a conventional magnetron sputtering system. The coating was applied using the following setting:
Target composition: Zr: Y: Si: Al=51:47:1.5:0.5 wt %;
Reactive sputtering in a mostly oxygen and argon containing atmosphere or from a ceramic target in a mostly argon containing atmosphere;
pressure: 1-8×10⁻³ mbar;
Coating thickness: 1000-1800 nm

The coating exhibits a good scratch resistance by a hardness of at least 6 GPa; a good heat resistance of ΔE=2 at 580° C.; a resistance to alkaline solutions (Na₂CO₃.aq, pH=10, T=20° C.;t12 h≥ΔE=0.8) and resistance to acid solutions (C₆H₈O₇.aq (citric acid), pH=3, T=20° C.; t 12 h≥ΔE=1.1).

### Example 6 (Inventive Example)

A glass ceramic substrate (SCHOTT CERAN®) having a size of 50 cm×50 cm×4 mm was cleaned, e.g. by a ultrasonic cleaner, by a brush washing machine, by flame pretreatment, by a temperature load or comparable known cleaning option. The sputtering process was carried out in a conventional magnetron sputtering system. The coating was applied using the following setting:

Target composition: Zr: Y: Si: Al: Hf=50,6:46,6:1,4:0,1:1.2 wt %; Reactive sputtering in a mostly oxygen and argon containing atmosphere or from a ceramic target in a mostly argon containing atmosphere;
pressure: 1-8×10⁻³ mbar;
Coating thickness: 1000-1800 nm

The coating exhibits a good scratch resistance by a hardness of at least 7 GPa; a good heat resistance of ΔE=0,32 at 580° C.; a resistance to alkaline solutions (Na₂CO₃.aq, pH=10, T=20° C.; t12h→ΔE=1) and resistance to acid solutions (C₆H₈O₇.aq (citric acid), pH=3, T=20° C.; t 12 h≥ΔE=1.5).

### Example 7 (Inventive Example)

A glass ceramic substrate (SCHOTT CERAN®) having a size of 50 cm×50 cm×4 mm was cleaned, e.g. by a ultrasonic cleaner, by a brush washing machine, by flame pretreatment, by a temperature load or comparable known cleaning option. The sputtering process was carried out in a conventional magnetron sputtering system. The coating was applied using the following setting:
Target composition: Zr: Y: Si=61,3:5,3:33.3 wt %;
Reactive sputtering in a mostly oxygen and argon containing atmosphere or from a ceramic target in a mostly argon containing atmosphere;
pressure: 1-8×10⁻³ mbar;
Coating thickness: 1000-1800 nm

The coating exhibits a good scratch resistance by a hardness of at least 4.5 GPa; a good heat resistance of ΔE=0,34 at 580° C.; a resistance to alkaline solutions (Na₂CO₃.aq, pH=10, T=20° C.; t 12 h≥ΔE=0,43) and resistance to acid solutions (C₆H₈O₇.aq (citric acid), pH=3, T=20° C.; t 12 h→ΔE=0,42).

### Example 8 (Inventive Example)

A glass ceramic substrate (SCHOTT CERAN®) having a size of 50 cm×50 cm×4 mm was cleaned, e.g. by a ultrasonic cleaner, by a brush washing machine, by flame pretreatment, by a temperature load or comparable known cleaning option. The sputtering process was carried out in a conventional magnetron sputtering system. The coating was applied using the following setting:
Target composition: Zr: Y: Si=46:4:50 wt %;
Reactive sputtering in a mostly oxygen and argon containing atmosphere or from a ceramic target in a mostly argon containing atmosphere;
pressure: 1-8×10⁻³ mbar;
Coating thickness: 1000-1800 nm

The coating exhibits a good scratch resistance by a hardness of at least 4.5 GPa; a good heat resistance of ΔE=0,46 at 580° C.; a resistance to alkaline solutions (Na₂CO₃.aq, pH=10, T=20° C.; t 12 h≥ΔE=0,29) and resistance to acid solutions (C₆H₈O₇.aq (citric acid), pH=3, T=20° C.; t 12 h≥ΔE=0,2).

### Example 9 (Inventive Example)

A glass ceramic substrate (SCHOTT CERAN®) having a size of 50 cm×50 cm×4 mm was cleaned, e.g. by a ultrasonic cleaner, by a brush washing machine, by flame pretreatment, by a temperature load or comparable known cleaning option. The sputtering process was carried out in a conventional magnetron sputtering system. The coating was applied using the following setting:
Target composition: Zr: Y: Si=30,6:2,6:66.6 wt %;
Reactive sputtering in a mostly oxygen and argon containing atmosphere or from a ceramic target in a mostly argon containing atmosphere;
pressure: 1-8×10⁻³ mbar;
Coating thickness: 1000-1800 nm

The coating exhibits a good scratch resistance by a hardness of at least 4.5 GPa; a good heat resistance of ΔE=0.5 at 580° C.; a resistance to alkaline solutions (Na₂CO₃.aq, pH=10, T=20° C.;t 12 h→ΔE=0,34) and resistance to acid solutions (C₆H₈O₇.aq (citric acid), pH=3, T=20° C.; t 12 h≥ΔE=0,9).

### Example 10 (Inventive Example)

A glass ceramic substrate (SCHOTT CERAN®) having a size of 50 cm×50 cm×4 mm was cleaned, e.g. by a ultrasonic cleaner, by a brush washing machine, by flame pretreatment, by a temperature load or comparable known cleaning option. The sputtering process was carried out in a conventional magnetron sputtering system. The coating was applied using the following setting:

Target composition: Zr: Y: Si: Al: Hf: C=50,6:46,6:1,4:0,1:1,1:0.2 wt %;
Reactive sputtering in a mostly oxygen and argon containing atmosphere or from a ceramic target in a mostly argon containing atmosphere;
pressure: 1-8×10⁻³ mbar;
Coating thickness: 1000-1800 nm

The coating exhibits a good scratch resistance by a hardness of at least 5 GPa; a good heat resistance of ΔE=0,7 at 580° C.; a resistance to alkaline solutions (Na₂CO₃.aq, pH=10, T=20° C.; t 12 ha ΔE=0,5) and resistance to acid solutions (C₆H₈O₇.aq (citric acid), pH=3, T=20° C.; t 12 h à ΔE=1,0).

### REFERENCE LIST

1 coated substrate
2 substrate
3 coating
4 decor
5 thickness of the coating

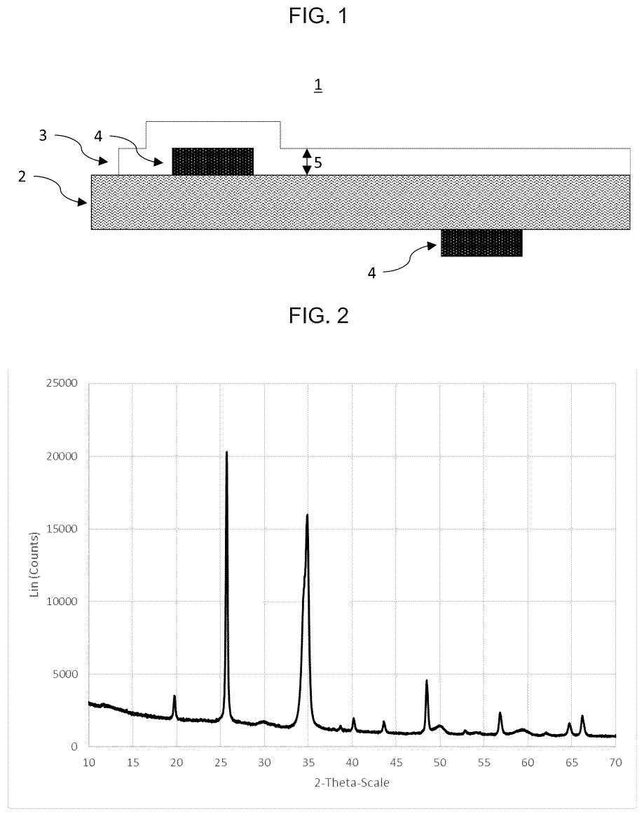

FIG. 1 shows a schematic depiction of a side view of a coated substrate 1 according to an embodiment. The substrate 1 is coated by the coating 3 having a thickness 5. Between the coating 3 and the substrate 2 or below the substrate 2 might be a decor 4. The decor 4 may also be deposited on the coating 3.

FIG. 2 shows an X-ray diffraction spectrum of example 1. As can be seen, there is a peak between 33° and 36° and further peak between 28° and 30° in the 2-theta-scale.

1-16. (canceled)

17. A coated substrate for a hob, comprising:
a substrate comprising a coating comprising a layer consisting of a composition A comprising yttrium and zirconium, wherein a content of zirconium in the composition A is 75 weight-% or less and a Martens hardness of the coating is 4.5 GPa or more, wherein, after a heat treatment, a color distance ΔE is 4.0 or less.

18. The coated substrate of claim 1, wherein the coating shows a peak between 33° and 36° and/or the coating shows a peak between 28° ad 30° in a 2-theta-scale of XRD analysis

19. A method for the production of a coated substrate, comprising the steps:
providing a substrate;
applying a layer consisting of a composition A comprising yttrium and zirconium by a physical vapor deposition process on the substrate to obtain the coated, wherein a content of zirconium in composition A is 75 weight-% or less.

20. The method of claim 19, wherein applying the layer on the substrate by the physical vapor deposition process comprises sputtering and depositing a target on the substrate, wherein the target comprises a composition B comprising yttrium, zirconium and unavoidable impurities, wherein a content of zirconium in composition B is 75 weight-% or less.

21. The method of claim 20, wherein at least one of the following is satisfied:
the target is a planar target or a rotatable target;
a magnetic flux density is set to 5 mT to 200 mT;
an applied electric current in the physical vapor deposition process is set to 1 A to 1000 A;
an applied voltage in the physical vapor deposition process is set to 50 V to 2000 V;
a pressure during the physical vapor deposition process is set to 0.5×10⁻³ bar to 1×10⁻² bar; or
a distance between the target and the substrate during the physical vapor deposition process is 2 to 40 cm.

22. The method of claim 20, wherein the composition A and/or the composition B further comprises one or more of silicon, aluminum, titanium, or hafnium.

23. The method of claim 20, wherein the content of yttrium in the composition A and/or the composition B is 25 weight-% or more.

24. The method of claim 20, wherein the composition A and/or the composition B comprises yttrium and zirconium, wherein the following equations are fulfilled:
((Zr/(Zr+Y))*100≥40; and
((Y/(Zr+Y))*100≥40, wherein Zr is the content (weight-%) of zirconium in the composition A and/or the composition B and Y is the content (weight-%) of yttrium in the composition A and/or the composition B, wherein a Martens hardness of the coating is 6 GPa or more and wherein, after a heat treatment, a color distance ΔE is 4 or less

25. The method of claim 24, wherein the composition A and/or the composition B further comprises silicon, wherein the following equations are fulfilled:
$$( ( Zr / ( Zr + Y + Si ) ) * 100 \geq 40 ;$$
$$( ( Y / ( Zr + Y + Si ) ) * 100 \geq 40 ;$$
and
0.1≤((Si/(Zr+Y+Si))*100≤4, wherein Zr is the content (weight-%) of zirconium in the composition A and/or the composition B, wherein Y is the content (weight-%) of yttrium in the composition A and/or the composition B, wherein Si is the content (weight-%) of silicon in the composition A and/or the composition B, wherein the Martens hardness of the coating is 6 GPa or more and wherein, after a heat treatment, the color distance ΔE is 4 or less.

26. The method of claim 25, wherein the composition A and/or the composition B further comprises aluminum, wherein the following equation is fulfilled:
0.5≤((Al/(Zr+Y+Si+Al))*1000≤50, wherein Al is the content (weight-%) of aluminum in the composition A and/or the composition B.

27. The method of claim 26, wherein the composition A and/or the composition B further comprises hafnium, wherein the following equation is fulfilled:
0.1≤ ((Hf/(Zr+Y+Si+Al+Hf))*100≤5, wherein Hf is the content (weight-%) of hafnium in the composition A and/or the composition B.

28. The method of claim 20, wherein the composition A and/or the composition B comprises zirconium, yttrium and silicon, wherein the following equations are fulfilled:
((Zr/(Zr+Y+Si))*100≥30;
and
((Y/(Zr+Y+Si))*100≤10, wherein Zr is the content (weight-%) of zirconium in the composition A and/or the composition B, Y is the content (weight-%) of yttrium in the composition A and/or the composition B, and Si is the content (weight-%) of silicon in the composition A and/or the composition B, wherein a Martens hardness of the coating is 4.5 GPa or more and wherein, after a heat treatment, a color distance ΔE is 4 or less.

29. The method of claim 28, wherein the following equation is fulfilled:
30≤((Si/(Zr+Y+Si))*100≤60, wherein, after a heat treatment, the color distance ΔE is 2 or less.

30. The method of claim 20, wherein the composition A and/or the composition B further comprises carbon.

31. The method of claim 19, wherein the substrate is at least one of a borosilicate glass, an alumosilicate glass, a lithiumalumosilicate glass, a soda-lime glass, a sapphire glass, a glass ceramic, or a lithiumalumosilicate glass ceramic.

32. The method of claim 31, wherein the substrate is chemically strengthened and/or thermally strengthened.

33. The method of claim 31, wherein the substrate is a not strengthened lithiumalumosilicate glass ceramic.

34. An article, comprising:
a coated substrate comprising a substrate comprising a coating comprising a layer consisting of a composition A comprising yttrium and zirconium, wherein a content of zirconium in the composition A is 75 weight-% or less and a Martens hardness of the coating is 4.5 GPa or more, wherein, after a heat treatment, a color distance ΔE is 4.0 or less, wherein the article is a hob, an oven, a table, a shower wall, a radiator, a car, a consumer electronic device, a mobile phone, a tablet, a watch, a smart watch, an optical filter, an interference filter, an anti-reflection filter, a mirror; an induction hob, a radiant hob or a gas hob.
